(19) United States
(12) Patent Application Publication
(10) Pub. No.: US 2010/0068831 A1
(43) Pub. Date: Mar. 18, 2010

(54) Method for wafer trimming for increased device yield

(75) Inventors: Bradley P. Barber, Acton, MA (US); Johncy Castelino, Burlington, MA (US); Edward Aspell, Methuen, MA (US)

Correspondence Address: Kathy Manke;Avago Technologies Limited, 4380 Ziegler Road, Fort Collins, CO, 80525, US

(73) Assignee: Skyworks Solutions, Inc., Woburn, MA (US)

(21) Appl. No.: 12/283,574

(22) Filed: Sep. 12, 2008

(51) Int. Cl. H01L 21/66; H01L 41/22

(52) U.S. Cl. 438/13; 29/25.35; 257/E21.53; 257/E21.531

(57) ABSTRACT

According to an exemplary embodiment, a method for site-specific trimming of a wafer to provide a target parameter value for a plurality of devices on the wafer includes performing a first measurement of a parameter at a subset of the number of devices on the wafer. The method further includes forming a top layer over the wafer after performing the first measurement. The method further includes performing a second measurement of the parameter at the subset of the devices on the wafer after forming the top layer. The method further includes determining an amount of the top layer to remove across the wafer to provide the target parameter value for the devices by utilizing the first and second measurements of the parameter. The method can be utilized to, for example, achieve a more uniform characteristic frequency for bulk acoustic wave (BAW) filters.

### BACKGROUND OF THE INVENTION

1. Field of the Invention

The present invention generally relates to the field of semiconductor fabrication. More particularly, the invention relates to wafer trimming in semiconductor fabrication.

2. Background Art

Because of their high performance, small size, and low cost, bulk acoustic wave (BAW) filters are increasingly utilized to provide radio frequency (RF) filtering in mobile communications devices, such as cellular phones, as well as other types of electronic devices. A BAW filter includes a multi-layer stack of films that determine, among other things, the operating frequency of the filter. During BAW filter fabrication, there can be a wide distribution of resultant operating frequencies after initial wafer processing due to non-uniformity of film deposition, which can undesirably affect device yield. As a result, a wafer trimming process is typically utilized, wherein a determined amount of material is removed from the top layer of the multi-layer film stack to achieve a target BAW filter operating frequency across the wafer.

In a conventional method of wafer trimming, the amount of material to be removed can be determined by utilizing a single pre-trimming measurement and a model to determine an average trim rate, which can be applied across the wafer to move a desired parameter from the pre-trim measured value to a desire final value. To reduce errors caused by fluctuations in film deposition and material parameters across the wafer and from lot-to-lot, the convention wafer trimming method can be improved by utilizing the errors found in trimming a pilot wafer in a concurrently fabricated lot as feedback so as to trim the remaining wafers in the lot more precisely. However, even with the improvement in the conventional wafer trimming method provided by the pilot wafer, non-uniform layer variations across the wafer can cause an undesirably high distribution in target operating frequencies across the wafer, which can undesirably reduce device yield. Also, the sacrifice of a pilot wafer in the conventional wafer trimming method is undesirable.

### SUMMARY OF THE INVENTION

A method for wafer trimming for increased device yield, substantially as shown in and/or described in connection with at least one of the figures, as set forth more completely in the claims.

### BRIEF DESCRIPTION OF THE DRAWINGS

FIG. 1 illustrates a cross-sectional view of an exemplary bulk acoustic wave structure in accordance with one embodiment of the present invention.

FIG. 2 illustrates a top view of an exemplary wafer including exemplary test sites in accordance with one embodiment of the present invention.

FIG. 3 shows a flowchart illustrating the steps taken to implement an embodiment of the present invention's method of site-specific wafer trimming.

FIG. 4A illustrates an exemplary contour map showing a site-specific rate of change of top layer thickness with respect to BAW filter characteristic frequency across a wafer in accordance with one embodiment of the present invention.

FIG. 4B illustrates a cross-sectional view of the exemplary contour map of FIG. 4A.

### DETAILED DESCRIPTION OF THE INVENTION

The present invention is directed to a method for wafer trimming for increased device yield. The following description contains specific information pertaining to the implementation of the present invention. One skilled in the art will recognize that the present invention may be implemented in a manner different from that specifically discussed in the present application. Moreover, some of the specific details of the invention are not discussed in order not to obscure the invention. The specific details not described in the present application are within the knowledge of a person of ordinary skill in the art.

The drawings in the present application and their accompanying detailed description are directed to merely exemplary embodiments of the invention. To maintain brevity, other embodiments of the invention which use the principles of the present invention are not specifically described in the present application and are not specifically illustrated by the present drawings.

As will be discussed in detail below, the present invention provides an innovative method for site-specific trimming of a wafer to achieve a more accurate target parameter value, such as a BAW (bulk acoustic wave) filter frequency, of devices, such as BAW filters, across the wafer. Although a characteristic frequency of a BAW filter is utilized as a target parameter value to illustrate the present invention, the present invention's method for site-specific wafer trimming can also be utilized for trimming films for on-wafer resistors and capacitors to advantageously provide tighter respective resistance and capacitance distributions across the wafer. In general, the invention's innovative method for site-specific wafer trimming can be utilized to provide a reduced distribution of target parameter values of devices or components fabricated on the wafer, where the devices or components have a target parameter value that is affected by film thickness over the wafer.

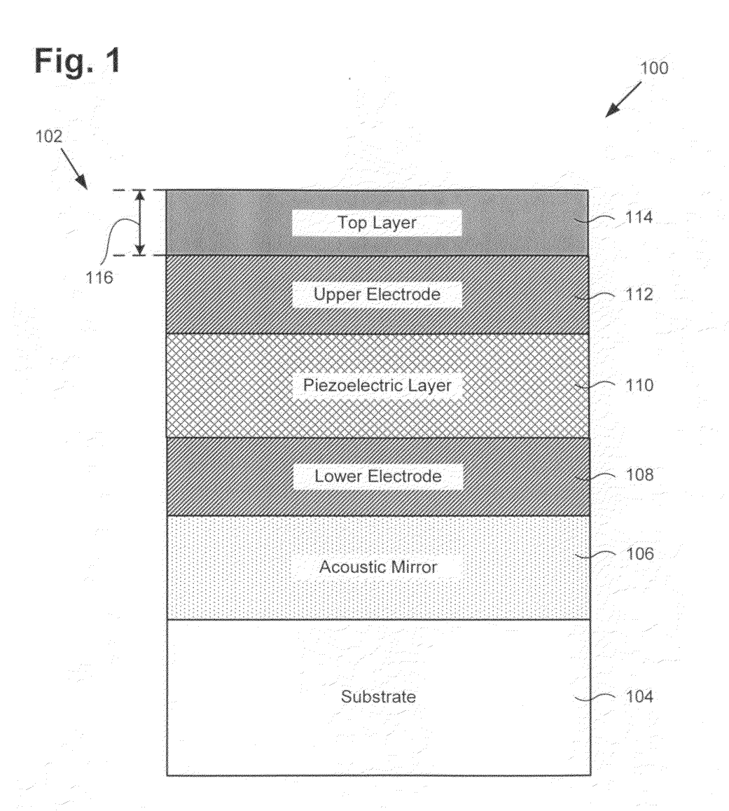

FIG. 1 shows a cross-sectional view of a semiconductor die including an exemplary BAW structure in accordance with one embodiment of the present invention. Certain details and features have been left out of FIG. 1, which are apparent to a person of ordinary skill in the art. In FIG. 1, structure 100 includes BAW structure 102 on substrate 104. BAW structure 102 includes acoustic mirror 106, lower electrode 108, piezoelectric layer 110, upper electrode 112, and top layer 114. BAW structure 102, which can be a BAW resonator, can be used in a device, such as a BAW filter or BAW RF filter, or as a resonator in a frequency control circuit, for example. In one embodiment, BAW structure 102 can be a film bulk acoustic resonator (FBAR), wherein a sacrificial layer can be utilized in place of acoustic mirror 106. In such embodiment, the sacrificial layer can be partially removed to form an air cavity for providing acoustic isolation from substrate 104.

As shown in FIG. 1, acoustic mirror 106 is situated over substrate 104, which can comprise, for example, silicon. Acoustic mirror 106 provides acoustical isolation between BAW structure 102 and substrate 104 and can comprise a selected number of alternating dielectric and metal layers, where each dielectric layer, which can comprise, for example, silicon oxide, provides a low acoustic impedance layer and each metal layer, which can comprise a high density metal, such as tungsten (W), provides a high acoustic impedance layer. In acoustic mirror 106, for example, each dielectric layer can be formed by using a chemical vapor deposition (CVD) process and each metal layer can be formed by using a physical vapor deposition (PVD) process.

Also shown in FIG. 1, lower electrode 108 is situated over acoustic mirror 106, piezoelectric layer 110 is situated over acoustic mirror 108, and upper electrode 112 is situated over piezoelectric layer 110. Lower electrode 108 and upper electrode 112 can each comprise molybdenum, tungsten, or other suitable high density metal and piezoelectric layer 110 can comprise aluminum nitride, zinc oxide, or other suitable piezoelectric material. Lower electrode 108 can be formed by, for example, depositing a layer of molybdenum on acoustic mirror 106 by using a PVD process or other suitable deposition process. Piezoelectric layer 110 can be formed, for example, by depositing a layer of aluminum nitride over lower electrode 108 by using a CVD process or other suitable deposition process. Upper electrode 112 can be formed by, for example, depositing a layer of molybdenum over piezoelectric layer 110 by using a PVD process or other suitable deposition process.

Further shown in FIG. 1, top layer 114 is situated over upper electrode 112 and can comprise silicon nitride, silicon dioxide (also referred to as “silicon oxide”), or other suitable material. In other embodiments, top layer 114 may comprise, for example, aluminum nitride or tungsten. In one embodiment, top layer 114 can be a passivation layer. Top layer 114 can be formed by, for example, depositing a layer of silicon nitride or other suitable material over upper electrode 112 by using a CVD process or other suitable deposition process. During fabrication, top layer 114 can be trimmed to thickness 116 by utilizing an embodiment of site-specific wafer trimming method so as to cause BAW structure 102 to have a target operating frequency.

During fabrication, a number of BAW devices, such as BAW filters, can be fabricated on a substrate of a wafer, which can be separated into individual semiconductor dies in a singulation process. Each BAW filter can be situated on a semiconductor die and can include a BAW structure, such as BAW structure 102. During fabrication, it is highly desirable that each BAW filter on the wafer have substantially the same target parameter value, such as a target characteristic frequency, so as to increase device yield and, thereby, reduce manufacturing cost.

The characteristic frequency of a BAW device, such as a BAW filter, can be a center frequency, a frequency that is a number of decibels (dB) on the right or left side of the filter frequency response curve relative to a peak insertion loss, or other specified operating frequency of the filter. For example, the characteristic frequency of the BAW filter that is used as a target frequency can be a frequency that is 10.0 dB less than and located to the high frequency side of the filter frequency response curve relative to the peak insertion loss. Non-uniformity of film deposition during wafer fabrication can result in an undesirably wide distribution of characteristic frequencies of respective BAW filters on the wafer, which can undesirably reduce device yield. Since the thickness of the top layer, such as top layer 114, on the wafer affects the characteristic frequency of the BAW filter, the top layer is typically deposited at a greater thickness than required and trimmed (reduced in thickness) in a trimming process to reduce the distribution of characteristic frequencies across the wafer and, thereby, improve the device yield.

In a conventional wafer trimming method, a top layer, such as a passivation layer, can be deposited over a wafer including a number of BAW devices, such as BAW filters, at a thickness greater than required to achieve a target characteristic frequency across the wafer. After the top layer has been deposited on the wafer, the characteristic frequency can then measured at a number of test sites across the wafer and an average “sensitivity” can be determined. For example, the test sites can be a subset of the number of devices on the wafer, where each test site can be, for example, a BAW device. The “sensitivity” refers to a rate of change of top layer thickness with respect to a parameter, such as characteristic frequency of a BAW filter, and can be expressed in Angstroms per MHz (or in nanometers (nm) per MHz, where 0.10 nm equals 1.0 Angstrom). Thus, a sensitivity value can represent a top layer thickness in Angstroms (or an equivalent thickness in nanometers) that can cause a characteristic frequency of a BAW device, such as a BAW filter, to shift or change by 1.0 MHz. For example, a sensitivity of 10 Angstroms/MHz (1.0 nm/MHz) indicates that a thickness of 10.0 Angstroms (1.0 nm) of a top layer can cause a 1.0 MHz change in the characteristic frequency of a BAW filter. The sensitivity can also be referred to as the reciprocal of the rate of change of a characteristic frequency with respect to top layer thickness.

In the conventional trimming method with a single measurement taken just before trimming, the average sensitivity can only be determined from previously trimmed wafers of a similar type or from a model. The amount of top layer material to be removed at each test site to achieve a target characteristic frequency can then be determined from the average sensitivity and the characteristic frequency measurement that was performed at each test site. In the conventional trimming process, a pilot wafer can then be trimmed in a site-specific etching tool by utilizing the previously determined amount of top layer material to be removed at each site. As a result of trimming the pilot wafer, a correction factor can be determined and utilized to provide a corrected average sensitivity, which can be utilized to trim subsequent wafers.

The conventional wafer trimming method is based on the assumption that sensitivity is uniform across the wafer and from wafer to wafer. In other words, the conventional wafer trimming method assumes that the removal of a selected thickness of top layer material anywhere on any wafer will cause the same change in a target parameter, such as a characteristic frequency of a BAW filter. However, sensitivity is a function of all of the layers of a BAW filter. Thus, the sensitivity can be different at each location of the wafer as a result of non-uniformity in film deposition across the wafer. For example, variations in thickness of a metal layer utilized to form upper electrodes, such as upper electrode 112, can cause corresponding variations in sensitivity across the wafer. As a result, the use of the average sensitivity in the conventional wafer trimming method can undesirably affect the characteristic frequency distribution of BAW filters across the wafer and, thereby, reduce device yield.

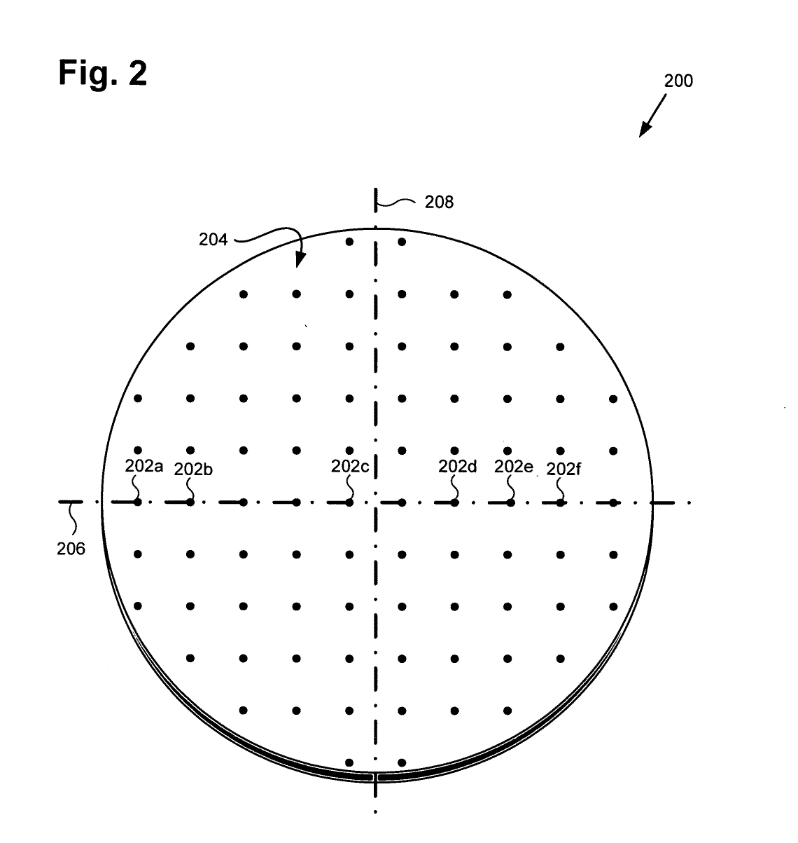

In contrast to the conventional wafer trimming method, one embodiment of the invention provides a site-specific wafer trimming method that utilizes two parameter measurements that are performed at each of a number of test sites on the wafer to determine a specific sensitivity for each test site, i.e., a site-specific sensitivity. In one embodiment, the test sites can be a subset of the number of devices on the wafer, where each test site can correspond to a device, such as BAW filter. In another embodiment, the test sites can be correspond to a number of test structures that are formed in the singulation streets between semiconductor dies on the wafer. In one embodiment, the site-specific sensitivity, i.e. a site-specific rate of change of top layer thickness per parameter, can be utilized to determine a thickness of top layer material to remove at each test site to provide a more precise target parameter value, such as a BAW filter target characteristic frequency, across the wafer, thereby increasing device yield. Also, one embodiment of the present site-specific method for wafer trimming does not require the sacrificing of a pilot wafer, as in the conventional method of wafer trimming. An embodiment of the invention's site-specific method for wafer trimming is further discussed below in relation to FIGS. 2, 3, 4A, and 4B.

FIG. 2 shows a top view of an exemplary wafer including multiple test sites in accordance with one embodiment of the present invention. Certain details and features have been left out of FIG. 2, which are apparent to a person of ordinary skill in the art. In FIG. 2, wafer 200 includes test sites 202a, 202b, 202c, 202d, 202e, and 202f (hereinafter “test sites 202a through 202f”), which are situated on top surface 204 of wafer 200. Wafer 200 can also include a number of BAW filters (not shown in FIG. 2), where each BAW filter can include a BAW structure, such as BAW structure 102 in FIG. 1. Each BAW filter (not shown in FIG. 2) can be situated on a separate semiconductor die, which can be separated from wafer 200 in a subsequent singulation or dicing process.

In FIG. 2, wafer 200 is shown at an intermediate stage of fabrication prior to deposition of a top layer, such as top layer 114, over top surface 204. Wafer 200 can include a large number of test sites, such as test sites 202a through 202f, which can be uniformly distributed over the wafer. It is noted that only test sites 202a through 202f are specifically discussed herein to preserve brevity. In one embodiment, the test sites 202a through 202f can be a subset of the number of devices on the wafer, where each of test sites 202a through 202f can correspond to a device, such as a BAW filter. Wafer 200 also includes horizontal centerline 206 and vertical centerline 208, which divide the wafer into substantially equal quarter sections.

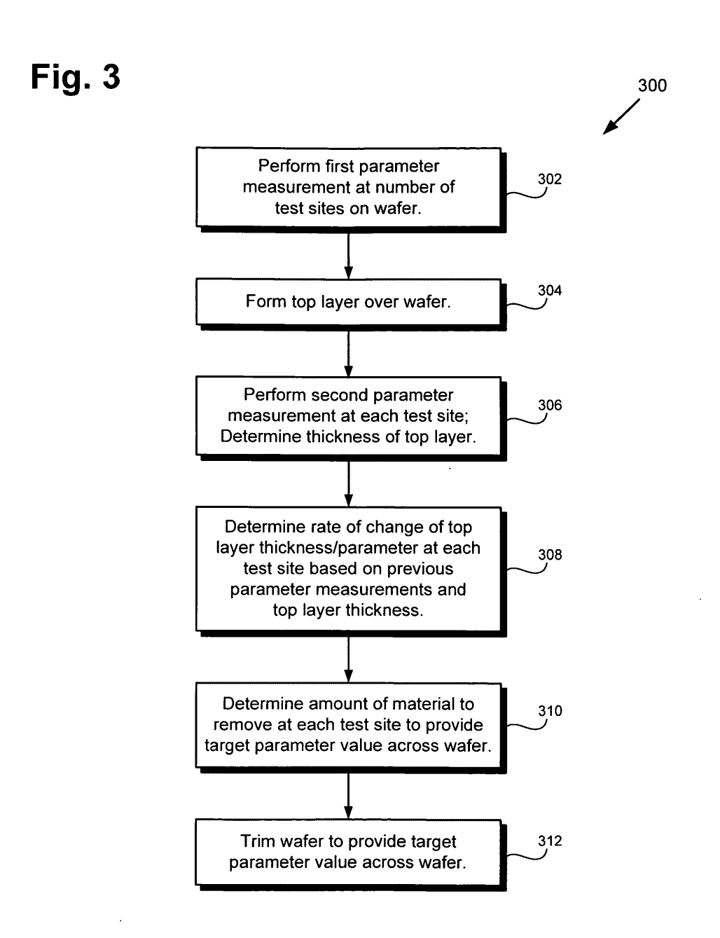

In wafer 200, each BAW filter (not shown in FIG. 2) has a characteristic frequency, which varies with respect to the thickness of the top layer of the wafer. An embodiment of the invention's site-specific method for wafer trimming, as discussed below in relation to flowchart 300 in FIG. 3, can be utilized to achieve an accurate target parameter value, such as a target characteristic frequency, across wafer 200 for the BAW filters situated thereon.

Referring now to FIG. 3, flowchart 300 illustrates an exemplary site specific method for trimming a wafer according to one embodiment of the present invention. Certain details and features have been left out of flowchart 300 that are apparent to a person of ordinary skill in the art. For example, a step may consist of one or more substeps or may involve specialized equipment or materials, as known in the art. It is noted that the processing steps shown in flowchart 300 are performed on wafer 200 in FIG. 2, which, prior to step 302 of flowchart 300, includes, among other things, a large number of test sites, such as test sites 202a through 202f, which can be, for example, uniformly distributed over the wafer. Wafer 200 also includes a number of BAW filters (not shown in FIG. 2), where each BAW filter can include a BAW structure, such as BAW structure 102 in FIG. 1. Prior to step 302 of flowchart 300, a top layer, such as top layer 114 in FIG. 1, remains to be deposited over top surface 204 of wafer 200.

At step 302 of flowchart 300, a first parameter measurement, such as a first characteristic frequency measurement, is performed at a number of test sites on wafer 200, such as test sites 202a through 202f. In one embodiment, the first parameter measurement can be performed at a subset of the number of devices on the wafer, where each test site can correspond to a device, such as a BAW filter. The first characteristic frequency measurement can provide a first set of data and can be performed using a standard wafer probe station. The first set of data can be utilized to generate a contour map of wafer 200 corresponding to the first characteristic frequency measurement. At step 304, a top layer, such as top layer 114 in FIG. 1, is deposited over top surface 204 of wafer 200. The top layer can comprise, for example, silicon nitride, and can be deposited at a thickness greater than an intended final thickness so as to allow the top layer to be trimmed by at least a small amount at every location across the wafer in a subsequent trimming process. In other embodiments, the top layer can comprise silicon oxide or other suitable material. The top layer can have a thickness of between 500.0 Angstroms (50.0 nm) and 2000.0 Angstroms (200.0 nm) in one embodiment.

At step 306, a second parameter measurement, such as a second characteristic frequency measurement, is performed at each of the test sites, such as test sites 202a through 202f, at which the first parameter measurement was performed and a thickness of the top layer is determined. The second characteristic frequency measurement can provide a second set of data and can be performed in a similar manner as the first characteristic frequency measurement. The second set of data can be utilized to generate a contour map of wafer 200 corresponding to the second characteristic frequency measurement. In one embodiment, prior to performing the second parameter measurement, a window can be opened in the top layer over each test site to expose it (i.e. the test site). In the present embodiment, the thickness of the top layer can be determined at each test site by measuring the top layer thickness by utilizing an optical measurement process or other suitable measurement. A set of data provided from the measurement of the top layer thickness at each test site can be utilized to generate a contour map of top layer thickness across the wafer. In one embodiment, the top layer thickness can be determined from a thickness map generated from a test wafer.

At step 308, a site-specific rate of change (i.e. a site-specific sensitivity) of top layer thickness per parameter (e.g. top layer thickness per characteristic frequency) is determined at each test site by using the respective sets of data from the first and second parameter measurements, such as the first and second characteristic frequency measurements, and the measured thickness of the top layer at each test site. For example, the site-specific sensitivity can be determined for each test site by dividing the top layer thickness at the test site by the difference between the first and second characteristic frequency measurements performed at that test site. A set of data corresponding to the site-specific rate of change of top layer thickness per parameter (e.g. top layer thickness per characteristic frequency) can be utilized to generate a contour map of site-specific sensitivity across the wafer. In one embodiment, an average top layer thickness can be used to determine the site-specific sensitivity in place of a top layer thickness that was determined for each test site. However, using an average top layer thickness can reduce the accuracy of the site-specific sensitivity. Thus, a site-specific sensitivity, i.e. a specific top layer thickness in Angstroms (or an equivalent thickness in nanometers) that is required to cause a 1.0 MHz shift in characteristic frequency is determined for each location on the wafer.

At step 310, an amount of top layer material to remove at each test site on wafer 200 is determined to achieve a target parameter value, such as a target characteristic frequency, at the test site. A set of data corresponding to the amount of top layer material, i.e., the thickness of top layer material, to remove at each test site can be utilized to generate a contour map of the thickness of top layer material to remove across the wafer to achieve a target characteristic frequency for all BAW filters on the wafer. At step 312, wafer 200 is trimmed to achieve a target parameter value across the wafer for all BAW filters on the wafer. Wafer 200 can be trimmed in trimming process by utilizing a site-specific etching tool, wherein the top layer of the wafer is etched according to the contour map of top layer material removal previously determined to provide the target characteristic frequency across the wafer. The site-specific etching tool can be, for example, a trim tool manufactured by TEL Epion Inc., located in Billerica, Mass., U.S.A (with one location presently at 37 Manning Road, Billerica, Mass. 01821, USA). In subsequent process step, wafer 200 can be separated into individual dies in a singulation process.

By utilizing two characteristic frequency measurements at each of a number of test sites on a wafer to determine a site-specific sensitivity, an embodiment of the present invention provides a method for site-specific trimming of a wafer to achieve a target characteristic frequency having increased accuracy and a reduced frequency spread across the wafer. In one embodiment of the invention, more than two characteristic frequency measurements can be performed at each test site to account for non-linearity in the rate of change of top layer material with a parameter, such as characteristic frequency of a BAW filter. By utilizing more that two characteristic frequency measurements to determine a site-specific sensitivity, a more precise target parameter, such as a target characteristic frequency, may be provided.

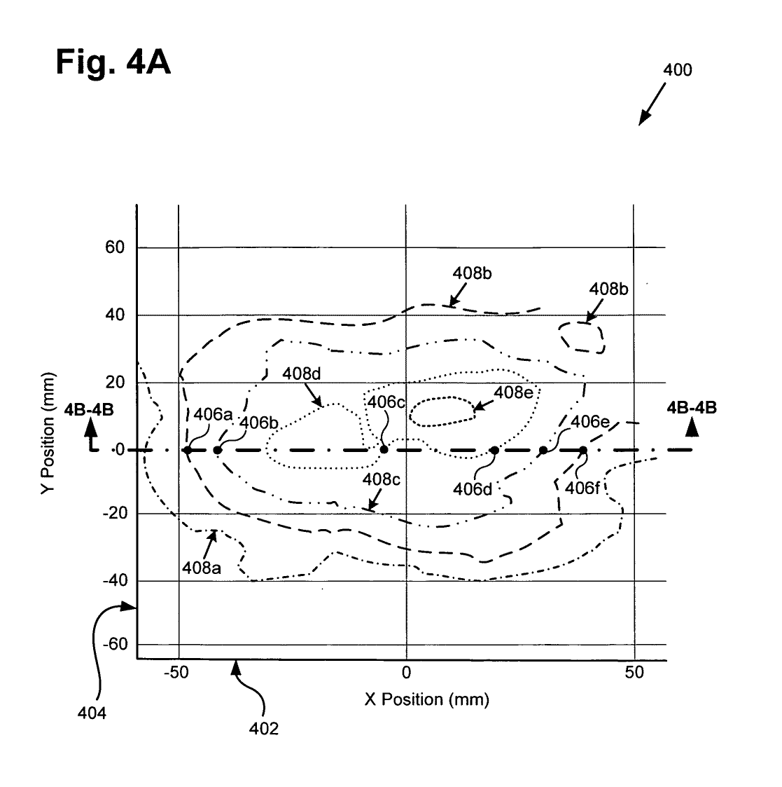

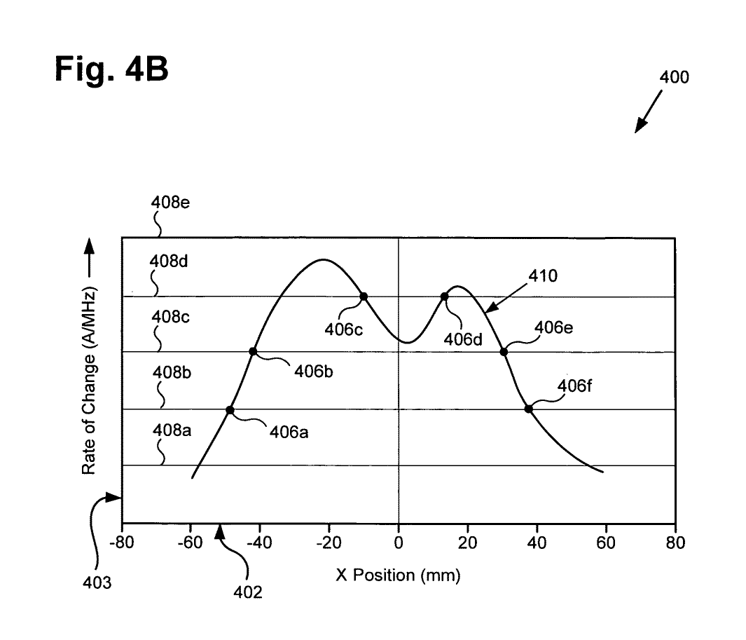

FIG. 4A shows an exemplary contour map of rate of change of a thickness of a top layer per frequency versus position across a wafer in accordance with one embodiment of the present invention. Contour map 400 includes x-position axis 402, y-position axis 404, test sites 406a, 406b, 406c, 406d, 406e, and 406f (hereinafter “test sites 406a through 406f”), and contour lines 408a, 408b, 408c, 408d, and 408e (hereinafter “contour lines 408a through 408e”). In contour map 400, x-position axis 402 and y-position axis 404 correspond to respective x and y coordinate positions on a top surface of a wafer, such as wafer 200 in FIG. 2, and test sites 406a through 406f correspond to respective test sites 202a through 202f. In contour map 400, contour lines 408a through 408e illustrate respective specific values of a rate of change of top layer thickness, such a thickness of top layer 114 in FIG. 1, with respective to characteristic frequency of a BAW filter.

In FIG. 4A, contour map 400 represents a contour map that can be provided as a result of performing step 308 in flowchart 300. As shown in FIG. 4A, test sites 406a and 406f are situated on contour line 408b, test sites 406b and 406e are situated on contour line 408c, and test sites 406c and 406d are situate on contour line 408d. For example, contour lines 408a through 408e can represent a respective rate of change of 16.5, 17.0, 17.5, 18.0 and 18.5 Angstroms/MHz (1.65, 1.70, 1.75, 1.80, and 1.85 nm/MHz) of top layer thickness per characteristic frequency of a BAW filter. Thus, FIG. 4A shows a contour map of a site-specific rate of change of top layer thickness per a parameter, such as a characteristic frequency of a BAW filter, which can be utilized to determine how much top layer material to remove across the wafer to provide a target characteristic frequency value for each BAW filter on the wafer in an embodiment of the invention.

FIG. 4B shows a cross-sectional view of contour map 400 in FIG. 4A across line 4B-4B in FIG. 4A. In particular, test sites 406a through 406f and contour lines 408a through 408e correspond to the same elements in FIG. 4A and FIG. 4B. In FIG. 4B, contour map 400 includes x-position axis 402, rate of change axis 403, and rate of change curve 410, which extends through test sites 406a through 406f. In contour map 400, rate of change axis 403 represents a site-specific rate of change of a thickness of a top layer on a wafer, such as wafer 200 in FIG. 2, with respect to frequency, such as a characteristic frequency of BAW filters situated on the wafer, as measured in nanometers per MHz. Rate of change axis 403 also indicates an increasing rate of change from contour line 408a to contour line 408e. In contour map 400, rate of change curve 410 represents variations in the site-specific rate of change of the thickness of the top layer of the wafer along line 4B-4B in FIG. 4A.

Thus, as shown in contour map 400 in FIGS. 4A and 4B, a site-specific rate of change (i.e. a site-specific sensitivity) of top layer thickness with respect to characteristic frequency of a BAW filter can be generated such that an embodiment of the invention provides a site-specific method of trimming a wafer with a higher precision of correction than conventional wafer trimming. As a result, an embodiment of the invention's site-specific method of wafer trimming provides a reduced distribution of target characteristic frequency values of BAW filters across the wafer, thereby increasing device yield.

Thus, as discussed above, by utilizing at least two parameter measurements at each of a number of test sites across the wafer to determine a site-specific rate of change of top layer thickness with respective to a parameter, such as a characteristic frequency of a BAW filter, the present invention's site-specific method of wafer trimming provides a reduced distribution of target parameter values, such as target characteristic frequency values, across the wafer. As a result, the present invention provides a site-specific method of wafer trimming that increases device yield compared to a conventional method of wafer trimming that utilizes an average rate of change of top layer thickness with respective to a parameter, such as a characteristic frequency of a BAW filter.

From the above description of embodiments of the present invention it is manifest that various techniques can be used for implementing the concepts of the present invention without departing from its scope. Moreover, while the present embodiments of the invention have been described with specific reference to certain embodiments, a person of ordinary skill in the art would appreciate that changes can be made in form and detail without departing from the spirit and the scope of the invention. Thus, the described embodiments are to be considered in all respects as illustrative and not restrictive. It should also be understood that the invention is not limited to the particular embodiments described herein but is capable of many rearrangements, modifications, and substitutions without departing from the scope of the invention.

1. A method for trimming of a wafer to achieve a target value of a parameter for a plurality of devices on said wafer, said method comprising steps of:
performing a first measurement of said parameter at a subset of said plurality of devices on said wafer;
forming a top layer over said wafer after said performing said first measurement;
performing a second measurement of said parameter at said subset of said plurality of devices after forming said top layer; and
utilizing said first and second measurements of said parameter to determine an amount of said top layer to remove across said wafer to achieve said target value of said parameter for said plurality of devices.

2. The method of claim 1, wherein said step of utilizing comprises using said first and second measurements to determine a site-specific rate of change of said parameter with a thickness of said top layer.

3. The method of claim 1 further comprising a step of measuring a thickness of said top layer prior to said step of utilizing said first and second measurements.

4. The method of claim 3, wherein said step of measuring said thickness of said top layer comprises measuring said thickness of said top layer at said subset of said plurality of devices on said wafer.

5. The method of claim 1 further comprising a step of trimming said wafer in a site-specific etching tool.

6. The method of claim 1, wherein each of said plurality of devices comprises a bulk acoustic wave (BAW) filter.

7. The method of claim 6, wherein said parameter comprises a characteristic frequency of said BAW filter.

8. The method of claim 1, wherein said step of performing said first measurement is utilized to determine a first parameter contour map of said wafer and said step of performing said second measurement is utilized to determine a second parameter contour map of said wafer.

9. The method of claim 8, wherein said step of utilizing comprises using said first and second parameter contour maps to determine a contour map of a site-specific rate of change of said parameter with a thickness of said top layer.

10. The method of claim 2, wherein said site-specific rate of change of said thickness of said top layer comprises dividing said thickness of said top layer by a difference between said first and second measurements of said parameter.

11. A method of site-specific wafer trimming to provide a target value of characteristic frequency for a plurality of bulk acoustic wave filters on said wafer, said method comprising steps of:
performing a first measurement of said characteristic frequency at a subset of said plurality of bulk acoustic wave filters on said wafer;
forming a top layer over said wafer after said performing said first measurement;
performing a second measurement of said characteristic frequency at said subset of said plurality of bulk acoustic wave filters after said forming said top layer; and
determining an amount of said top layer to remove across said wafer to provide said target value of said characteristic frequency for said plurality of bulk acoustic wave filters by utilizing said first and second measurements of said characteristic frequency.

12. The method of claim 11, wherein said step of determining said amount of said top layer to remove across said wafer comprises using said first and second measurements to determine a site-specific rate of change of said characteristic frequency with a thickness of said top layer.

13. The method of claim 11, further comprising a step of measuring a thickness of said top layer prior to said determining said amount of said top layer to remove.

14. The method of claim 13, wherein said step of measuring said thickness of said top layer comprises measuring said thickness of said top layer at each of said subset of said plurality bulk acoustic wave filters.

15. The method of claim 11, further comprising a step of trimming said wafer using a site-specific etching tool.

16. (canceled)

17. (canceled)

18. The method of claim 11, further comprising:
determining a first characteristic frequency contour map of said wafer based on said first measurement; and
determining a second characteristic frequency contour map of said wafer based on said second measurement.

19. The method of claim 18, wherein said step of determining said amount of said top layer to remove comprises utilizing said first and second contour maps to determine a contour map of a site-specific rate of change of said characteristic frequency with a thickness of said top layer.

20. The method of claim 12, wherein said site-specific rate of change of said thickness of said top layer is determined by dividing said thickness of said top layer by a difference between said first and second measurements of said parameter.
